(19) United States
(12) Patent Application Publication
(10) Pub. No.: US 2005/0055622 A1
(43) Pub. Date: Mar. 10, 2005

(54) Device and method for generating error correction code

(76) Inventor: Yuichiro Tsukamizu, Inuyama-shi (JP)

Correspondence Address: FISH & RICHARDSON PC, 225 FRANKLIN ST, BOSTON, MA, 02110, US

(21) Appl. No.: 10/932,398

(22) Filed: Sep. 2, 2004

(30) Foreign Application Priority Data
Sep. 5, 2003 (JP) 2003-313751
Sep. 8, 2003 (JP) 2003-315673

(51) Int. Cl. H03M 13/00

(52) U.S. Cl. 714/758

(57) ABSTRACT

A device for generating an error correction code for DVD block data including data units represented by symbols arranged an array of rows and columns. A PO calculation circuit.sequentially reads data for the symbols for each column to calculate an outer code parity. A PI calculation circuit acquires the data for the symbols read by the PO calculation circuit to intermittently calculate an inner code parity for each row. A temporary memory temporarily holds the calculation result of the PI calculation circuit.

### CROSS-REFERENCE TO RELATED APPLICATIONS

This application is based upon and claims the benefit of priority from prior Japanese Patent Application Nos. 2003-313751, filed on Sep. 5, 2003, and 2003-315673, filed on Sep. 8, 2003, the entire contents of which are incorporated herein by reference.

### BACKGROUND OF THE INVENTION

The present invention relates to a device and method for generating two types of error correction codes.

FIG. 1 is a schematic block diagram of a data recording device for a digital versatile disc (DVD). The data recording device includes a digital signal processing device 200 for receiving write data from a host computer and performing a predetermined digital process on the write data. The digital signal processing device 200 temporary stores the digitally processed write data in a buffer memory 300, such as a synchronous dynamic random access memory (SDRAM).

The digital signal processing device 200 provides data to an analog signal processing circuit 310, which performs an analog process on the data to provide an analog signal to a pickup 320. In accordance with the analog signal, the pickup 320 emits a laser beam to a DVD 330. A microcomputer 340 controls the digital signal processing device 200, the analog signal processing circuit 310, and the pickup 320.

The processing performed by the digital signal processing device 200 will now be discussed in further detail.

The write data provided from the host computer is transferred via a host interface 210 to a memory interface 220. An address generation circuit 230 generates address data for the buffer memory 300. In accordance with the generated address data, the memory interface 220 accesses a corresponding storage section of the buffer memory 300 and writes the write data to that storage section.

In accordance with the address data generated by the address generation circuit 230, the memory interface 220 accesses the corresponding storage section of the buffer memory 300 and mediates the transfer of data between the buffer memory 300 and various circuits in the digital signal processing device 200. This enables various digital processes to be performed on the data stored in the buffer memory 300.

An IED processing circuit 240 adds two bytes of an ID error detection code (IED) to each sector in DVD data format for the data stored in the buffer memory 300. Further, an EDC processing circuit 250 adds four bytes of an error detection code (EDC) to each sector. A scramble processing circuit 260 performs a scramble process on the data transferred from the host computer.

An ECC processing circuit 270 adds an error correction code to the data to which the IED and EDC have been added and which have undergone the scramble process. An 8-16 modulation circuit 280 then performs an interleave process, an 8-16 modulation process, and an NRZI modulation process on the data to which the error correction code has been added. The processed data is transferred from the 8-16 modulation circuit 280 to the analog signal processing circuit 310.

The processing performed by the ECC processing circuit 270 will now be discussed.

FIG. 2 shows a block of DVD data, that is, a code word including error correction codes. The corrected code that is to be corrected by the error correction codes has 192 rows of 172 bytes and is indicated by symbols “B_{i,j}” (i is 0 to 191, and j is 0 to 171). Each symbol represents eight bits of data, or a data unit. FIG. 2 shows an array of symbols arranged in rows and columns.

Outer code parities (PO) B_{192,0}-B_{207,0}, B_{192,1}-B_{207,1}, . . . , and B_{192,171}-B_{207,171}, each having sixteen bytes, are respectively added to columns B_{0,0}-B_{191,0}, B_{0,1}-B_{191,1}, . . . , and B_{0,171}-B_{191,171} of the corrected code. Further, inner code parities (PI) B_{0,172}-B_{0,181}, B_{1,172}-B_{1,181}, . . . , and B_{191,172}-B_{191,181}, each having ten bytes, are respectively added to the rows B_{0,0}-B_{0,171}, B_{1,0}-B_{1,171}, . . . , and B_{191,0}-B_{191,171} of the corrected code. Inner code parities B_{192,172}-B_{192,181}, . . . , and B_{207,172}-B_{207,181} are also respectively added to the rows of outer code parities B_{192,0}-B_{192,171}, . . . , B_{207,0}-B_{207,171}.

In this manner, one block of DVD data includes two types of error correction codes, the outer code parities and the inner code parities. The two types of error correction codes are calculated by the ECC processing circuit 270 shown in FIG. 1. The ECC processing circuit 270 includes an calculation section 271 and a latch section 272. The calculation section 271 calculates an error correction code based on the data for each symbol and the data latched by the latch section 272.

For example, when calculating the outer code parity B_{192,0}-B_{207,0} of the 0th row, the ECC processing circuit 270 sequentially reads the data of each of the symbols B_{0,0}-B_{191,0} in the symbol group of the 0th column. The calculation result, which has the same data amount (sixteen bytes) as the outer code parity, is latched by the latch section 272. Then, the data for the symbol B_{0,171} in the final column of the 0th row of the corrected code is read to obtain the inner code parity of that row.

The digital signal processing device 200 of FIG. 1 performs time-sharing processes as schematically shown in FIG. 3. In FIG. 3, (a) and (b) each show the block corresponding to the data transferred from the host interface 210 to the buffer memory 300. Further, (c) to (h) in FIG. 3 respectively show the block corresponding to the data to which an IED has been added, the data to which an EDC has been added, the data that has undergone the scramble process, the data to which an outer code parity has been added, the data to which an inner code parity has been added, and the data that has been processed by the 8-16 modulation circuit.

Japanese Laid-Open Patent Publication No. 10-63433 describes a prior art method for correcting errors.

In the digital signal processing device 200 that accesses the buffer memory 300 in a time-sharing manner as shown in FIG. 3, the ECC processing circuit 270 occupies the access to the buffer memory 300 during the calculation of the error correction code. When access to the buffer memory 300 is occupied, the other processing circuits must wait to access the buffer memory 300.

As shown by (f) and (g) in FIG. 3, the ECC processing circuit 270 first calculates the outer code parity. Then, after the calculation of the outer code parity is completed, the ECC processing circuit 270 calculates the inner code parity. The calculation of the two types of error correction codes occupies the buffer memory 300 for a long period. Thus, it is difficult to increase the processing speed of the digital signal processing device when, for example, recording data to the DVD 330 at double speed.

### SUMMARY OF THE INVENTION

One aspect of the present invention is a method for generating an error correction code for data units represented by symbols arranged in an array of rows and columns. Either one of each row of symbols and each column of symbols defines a first symbol group and the other one thereof defines a second symbol group. A first error correction code is added to each of the first symbol groups. A second error correction code is added to each of the second symbol groups. The method including sequentially reading data for each symbol of each first symbol group and continuously calculating the first error correction code corresponding to that first symbol group, and acquiring the data for each symbol used to calculate the first error correction code corresponding to each first symbol group and intermittently calculating the second correction codes corresponding to the second symbol groups. Intermediate data is generated when the second error correction codes are being calculated. The method further includes temporarily holding the intermediate data. The step for acquiring data for each symbol used to calculate the first error correction code includes calculating the second error correction codes based on the data for the symbols read in said sequentially reading data for each symbol of each first symbol group and the temporarily held intermediate data. The step for temporarily holding the intermediate data includes updating the temporarily held intermediate data whenever said acquiring data for each symbol used to calculate the first error correction code is performed.

Another aspect of the present invention is a device for generating an error correction code for data units represented by symbols arranged in an array of rows and columns. Either one of each row of symbols and each columns of symbols defines a first symbol group and the other one thereof defines a second symbol group. A first error correction code is added to each of the first symbol groups. A second error correction code is added to each of the second symbol groups. The device includes a first calculation circuit for sequentially reading data for each symbol of each first symbol group and continuously calculating the first error correction code corresponding to that first symbol group. A second calculation circuit acquires the data for each symbol read by the first error correction and intermittently calculates the second correction codes corresponding to the second symbol groups. The second calculation circuit generates intermediate data when the second error correction codes are being calculated. A temporary memory, connected to the second calculation circuit, temporarily holds the intermediate data. The second calculation circuit retrieves the intermediate data from the temporary memory, performs a predetermined calculation with the intermediate data and the acquired data for each symbol, and updates the temporarily held intermediate data.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a schematic block diagram of a prior art DVD data recording device;

FIG. 2 is a diagram showing a code word including DVD error correction codes;

FIG. 3 is a time chart showing the order in which the prior art data recording device performs time-sharing digital processes;

FIG. 4 is a schematic block diagram of an error correction code generation device according to a preferred embodiment of the present invention;

FIG. 5 is a flowchart showing a method for generating an error correction code according to a preferred embodiment of the present invention;

FIGS. 6 and 7 are time charts of a process for calculating the inner and outer code parities in the preferred embodiment of the present invention; and

FIG. 8 is a time chart showing the order in which the time-sharing digital processes are performed in the preferred embodiment of the present invention.

### DETAILED DESCRIPTION OF THE PREFERRED EMBODIMENTS

A method and device for generating an error correction code according to a preferred embodiment of the present invention will now be discussed.

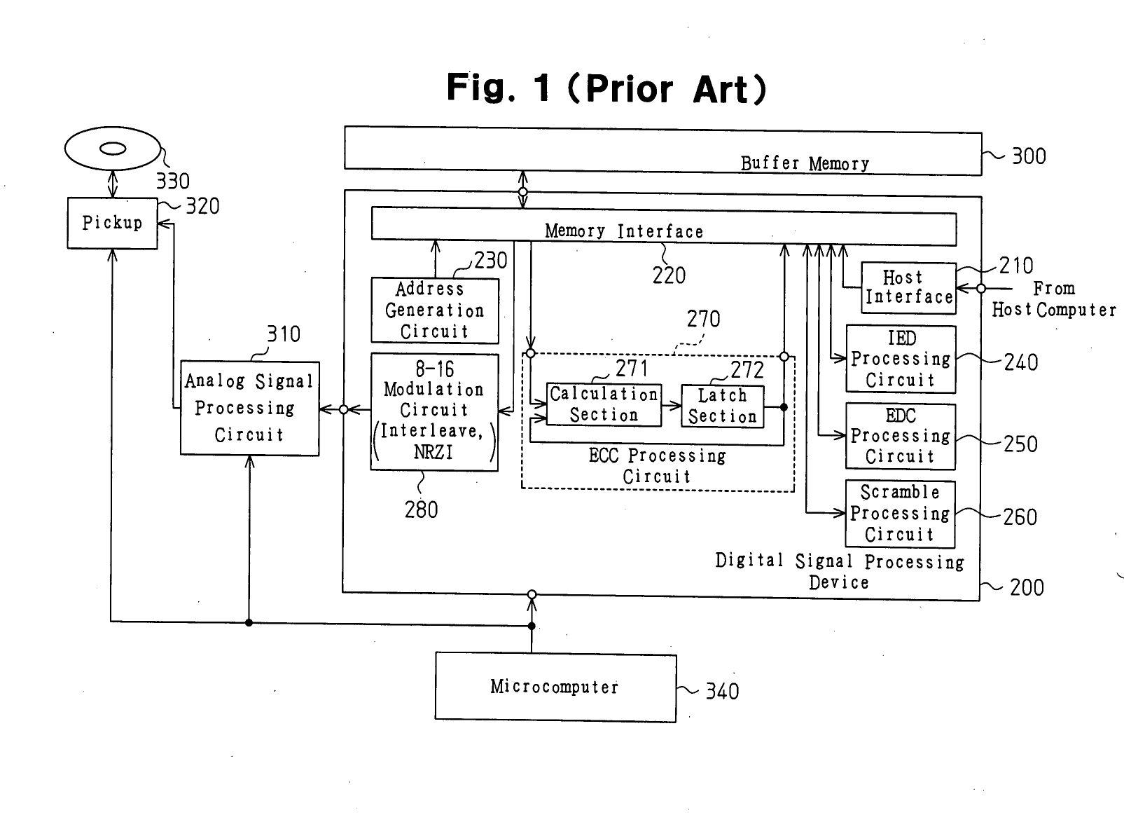

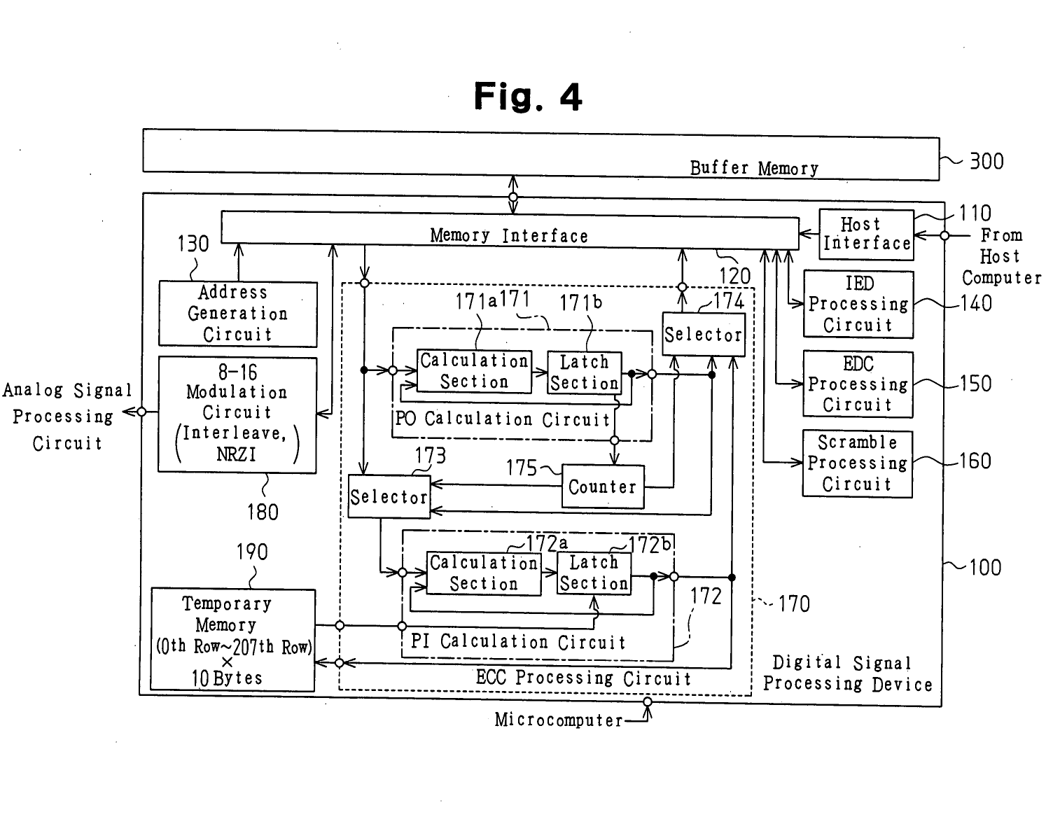

FIG. 4 is a schematic diagram of a digital signal processing device 100 incorporated in a DVD data recorder. The digital signal processing device 100 is used with a buffer memory 300. The digital signal processing device 100 is a modification of the digital signal processing device 200 shown in FIG. 1. The microcomputer 340, the analog signal processing circuit 310, and the pickup 320 shown in FIG. 1 are incorporated in the DVD data recorder and arranged near the digital signal processing device 100 and the buffer memory 300.

The digital signal processing device 100 includes a host interface 110, a memory interface 120, an address generation circuit 130, an IED processing circuit 140, an EDC processing circuit 150, a scramble processing circuit 160, an ECC processing circuit 170, and an 8-16 modulation circuit 180. The host interface 110, the memory interface 120, the IED processing circuit 140, the EDC processing circuit 150, and the scramble processing circuit 160 are identical to the corresponding circuits of FIG. 1.

The ECC processing circuit 170 will now be discussed.

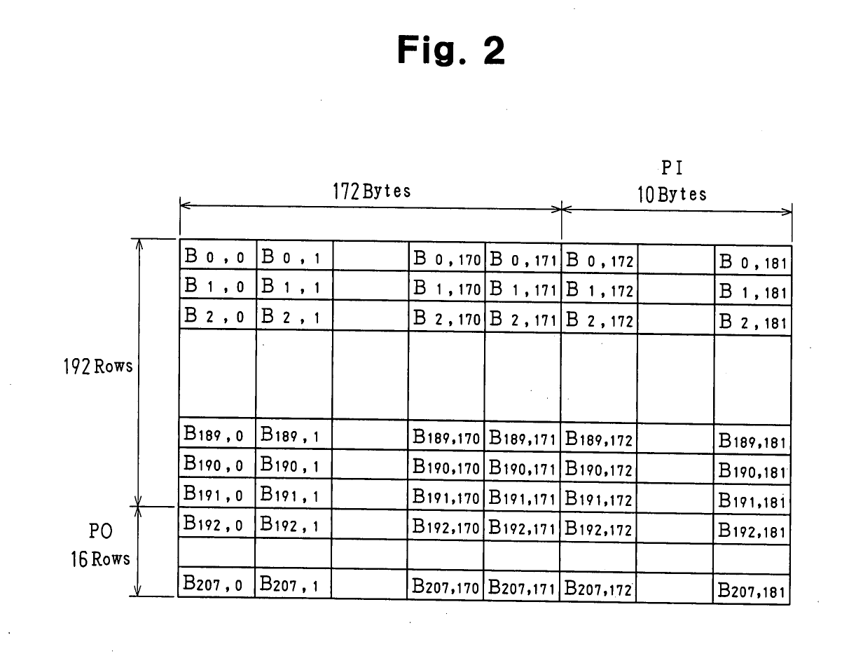

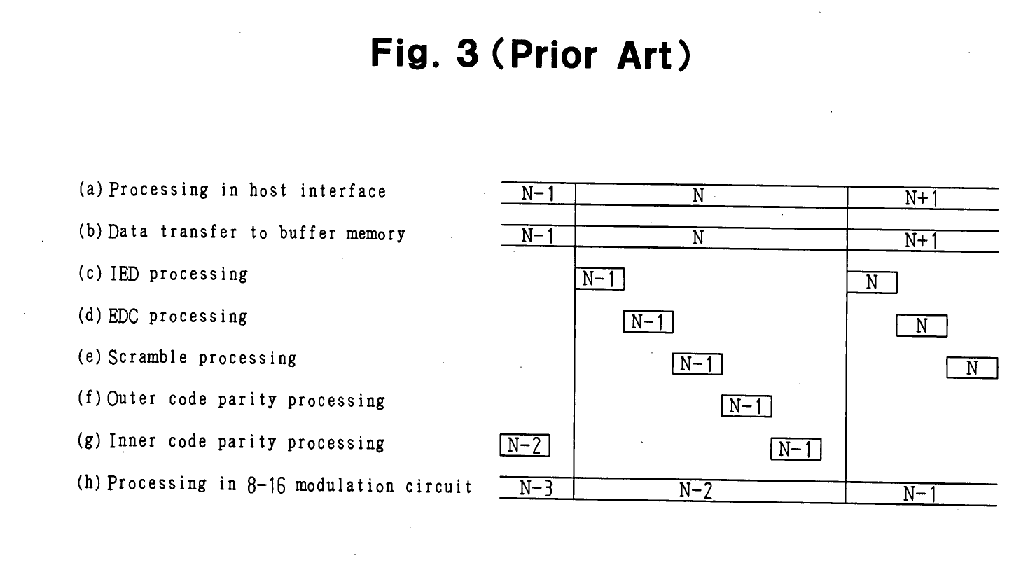

The ECC processing circuit 170 includes an outer code parity (“PO”) calculation circuit 171 and an inner code parity (“PI”) calculation circuit 172. The PO calculation circuit 171 sequentially reads the data for the symbols in each of the columns, or symbol groups, shown in FIG. 2, to continuously perform calculation of outer code parities. The PI calculation circuit 172 acquires the data for the symbols read by the PO calculation circuit 171 to intermittently perform calculation of inner code parities. The PO calculation circuit 171 includes a PO calculation section 171a and a latch section 171b. The PO calculation section 171a calculates an outer code parity based on the sixteen bytes of data latched by the latch section 171b and the data for each symbol read from an external circuit, or the buffer memory 300. The PI calculation circuit 172 includes a PI calculation section 172a and a latch section 172b. The PI calculation section 172a calculates an inner code parity based on the ten bytes of data latched by the latch section 172b and the acquired data for each symbol.

The ECC processing circuit 170 includes a selector 173 for providing data to the PI calculation circuit 172. The selector 173 selects the data for the symbol provided to the PO calculation circuit 171 and the data for each symbol forming the outer code parity output from the PO calculation circuit 171. The ECC processing circuit 170 includes a further selector 174 for selecting the outer code parity calculated by the PO calculation circuit 171 or the inner code parity calculated by the PI calculation circuit 172. The selected parity is selectively provided to the memory interface 120 at a predetermined timing. The ECC processing circuit 170 includes a counter 175 for counting the number of times the data latched by the latch section 171b of the PO calculation circuit 171 is updated. The selectors 173 and 174 perform switching control in accordance with the count value of the counter 175.

The calculation result of the PI calculation circuit 172, or the ten bytes of data latched by the latch section 172b, is temporarily held in a temporary memory 190, such as a static random access memory (SRAM). In correspondence with the number of bytes in each row of the inner code parities B_{0,172}-B_{0,181}, B_{1,172}-B_{1,181}, . . . , and B_{191,172}-B_{191,181}, the temporary memory 190 includes ten byte storage sections.

The calculation process for the inner and outer code parities will now be discussed.

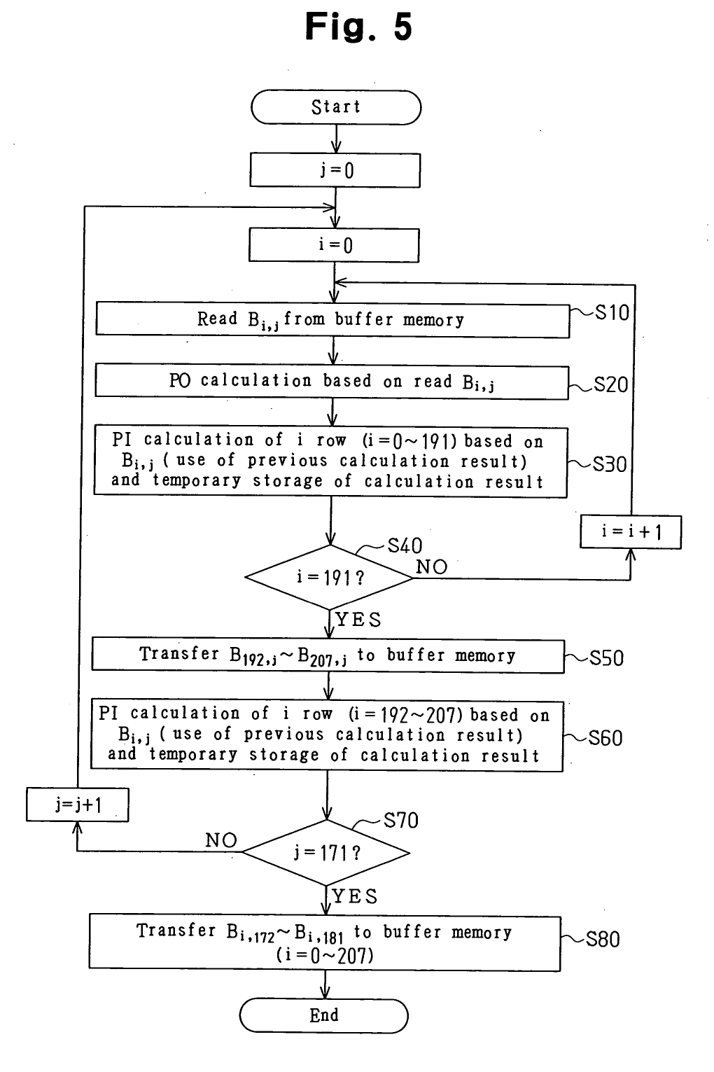

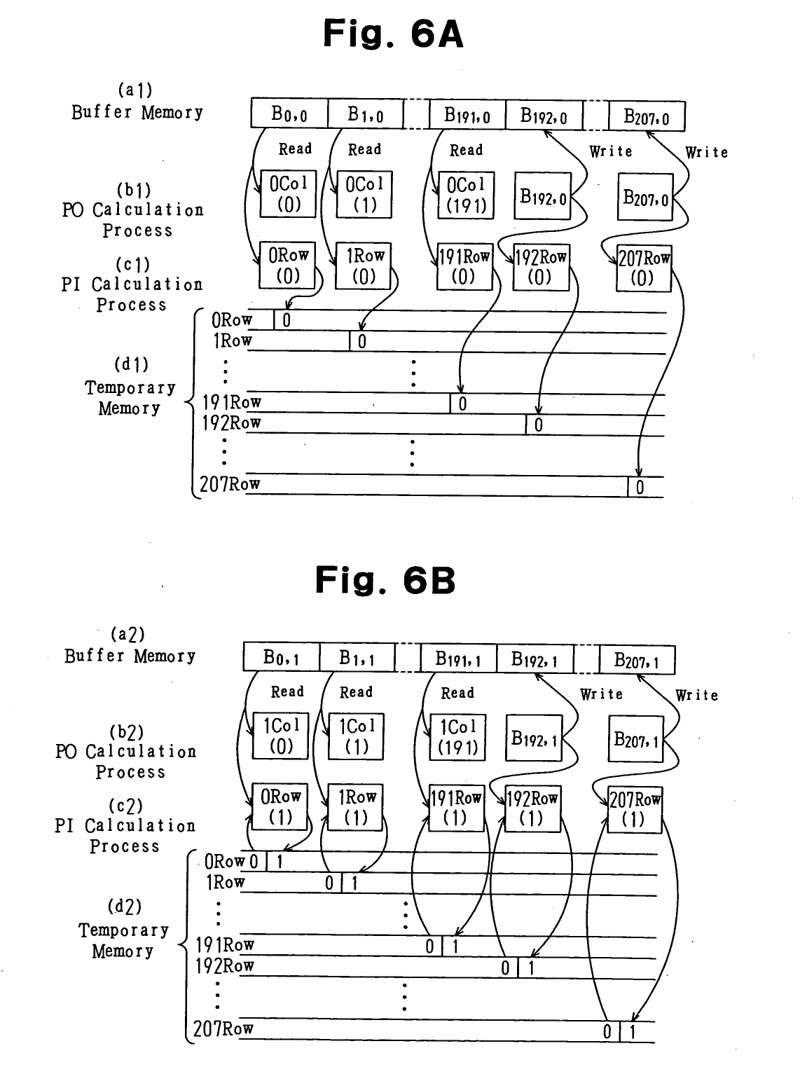

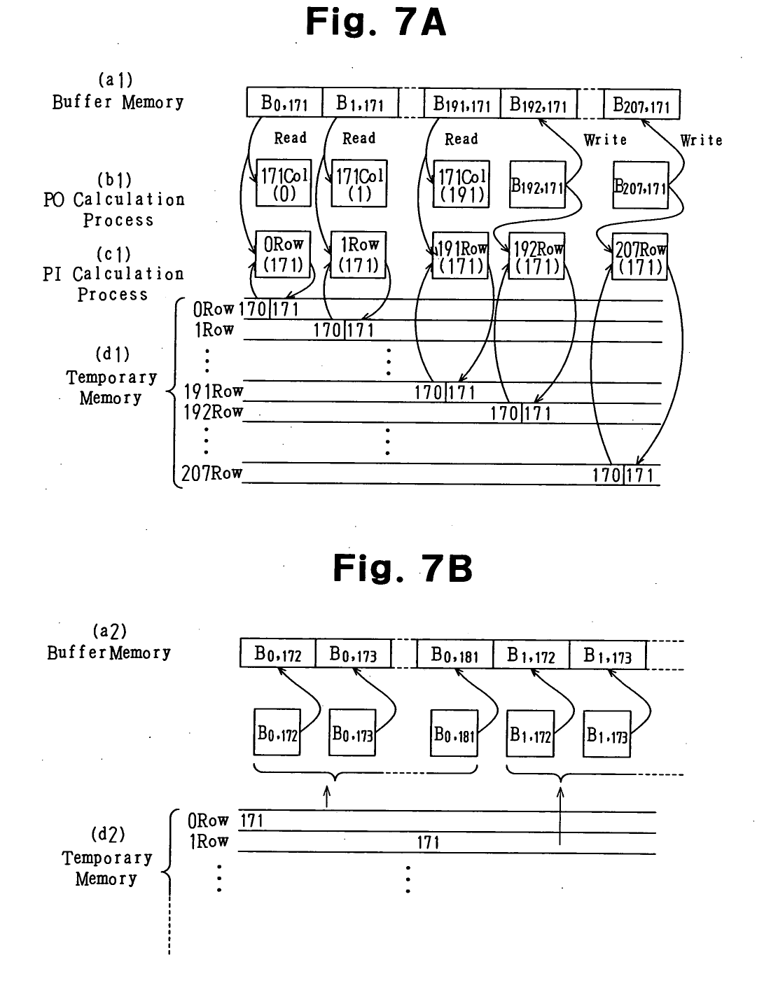

FIG. 5 shows a process for calculating the inner and outer code parities. FIGS. 6A, 6B, 7A, and 7B are time charts for the calculation process of the inner and outer code parities. The data for the symbol that is processed when accessing the buffer memory 300 is shown by (a1) in FIG. 6A, (a2) in FIG. 6B, (a1) in FIG. 7A, and (a2) in FIG. 7B. The calculation result for the PO calculation circuit 171 (the sixteen bytes of data latched by the latch section 171b) is shown by (b1) in FIG. 6A, (b2) in FIG. 6B, and (b1) in FIG. 7A. The calculation result for the PI calculation circuit 172 (the ten bytes of data latched by the latch section 172b) is shown by (c1) in FIG. 6A, (c2) in FIG. 6B, and (c1) in FIG. 7A. The data stored in each storage section of the temporary memory 190 that is allocated to a corresponding row of an inner code parity is shown by (d1) in FIG. 6A, (d2) in FIG. 6B, (d1) in FIG. 7A, and (d2) in FIG. 7B.

When the process of FIG. 5 starts, first, in step S10, among the data for the symbols configuring the block stored in the buffer memory 300, the data for the symbols configuring the symbol group to which the outer code parity is added is sequentially read. For example, the data for the symbols configuring the symbol group B_{0,0}-B_{191,0} of the 0th column is sequentially read. Then, the data for the symbols configuring the symbol group B_{0,1}-B_{191,1} of the 1st column is sequentially read. The buffer memory 300 is accessed based on the address generated by the address generation circuit 130 shown in FIG. 4.

In step S20, whenever the data for a symbol is read, the PO calculation circuit 171 performs an outer code parity calculation process with the data latched by the latch section 171b and the newly read symbol data. The latch section 171b then latches the newly calculated data. The new sixteen bytes of data obtained by reading and processing the data for each symbol, or the new data latched by the latch section 171b, is shown by (b1) in FIG. 6A and (b2) in FIG. 6B. For example, the processing result based on the data for the symbol B_{0,0} in the 0th column of the 0th row is “0th column (0)”, and the processing result based on the data for the symbol B_{1,0} in the 0th column of the 1st row is “0th column (1)”.

Prior to retrieving the data for the symbols B_{0,0}, B_{0,1}, . . . of each column in the 0th row, the latch section 171b is initialized. The PO calculation circuit 171 performs processing based on the initial data output from the initialized latch section 171b and the data for the symbol in the 0th row. When reading and processing the data for each symbol in each column of the 1st to 191st rows, the PO calculation circuit 171 uses the sixteen bytes of data (intermediate data) latched by the latch section 171b, or the previous calculation result. For example, when the data for symbol B_{1,0} in the 0th column of the first row is read, the intermediate data “0th column (0)” is used. When the data for symbol B_{1,1} in the 1st column of the first row is read, the intermediate data “1st column (0)” is used.

In step S30, as shown by (c1) in FIG. 6A and (c2) in FIG. 6B, the PI calculation circuit 172 acquires the data for each symbol read in the PO calculation circuit 171.

The order of the symbols acquired in the PI calculation circuit 172 does not coincide with the order of the symbols that are read to calculate the inner code parity. Thus, the processing result of the PI calculation circuit 172, or the ten bytes of data latched by the latch section 172b, is sequentially stored in the corresponding storage sections of the temporary memory 190.

More specifically, as shown by (d1) and (d2) in FIGS. 6A and 6B, for example, whenever the PO calculation circuit 171 reads the data for the symbols B_{0,0}-B_{191,0} in the 0th row, the PI calculation circuit 172 temporarily stores the intermediate data “0th row (0)”, “1st row (0)”, . . . , “191st row (0)” in the corresponding storage section of the temporary memory 190. For example, when the PO calculation circuit 171 reads the data for the symbols B_{0,1}-B_{191,1} in the first column to calculate the outer code parity, the PI calculation circuit 172 temporarily stores the intermediate data “0th row (0)”, “1st row (0)”, . . . , “191st row (0)” in the corresponding storage section of the temporary memory 190.

As shown by (c1) in FIG. 6A, prior to the calculation process for the outer code parity using the data for each symbol in the 0th row, the PI calculation circuit 172 initializes the latch section 172b. The PI calculation circuit 172 performs the calculation process for the outer code parity based on the initial data output from the initialized latch section 172b and the data for the symbols in the 0th row. In synchronism with the timing for reading from the buffer memory 300 the data for each symbol in the 1st column to the 171st column by the PO calculation section 171a to calculate outer code parities, the latch section 172b retrieves the previous processing result (intermediate data) stored in the temporary memory 190 to calculate the inner code parity corresponding to the read symbol data. For example, when the data for the symbol B_{0,1} in the 1st column of the 0th row is read from the buffer memory 300, the intermediate data “0th row (0)” is retrieved from the temporary memory 190. Further, when the data for the symbol B_{1,1} in the 1st column of the 1st row is read from the buffer memory 300, the intermediate data “1st row (0)” is retrieved from the temporary memory 190. When storing the intermediate data of the inner code parity that is being calculated in the temporary memory 190, the previous intermediate data for the inner code parity is overwritten. In other words, the corresponding intermediate data held by the temporary memory 190 is updated.

In step S40, the selector 173 checks of the completion of the processing of the data for the symbols from the 0th row to the 191st row in each column. This is performed by checking the number of times the data latched by the latch section 171b is updated, which is counted by the counter 175.

In each column, at the point of time when processing is performed based on the data for the symbols in each column of the 0th to 191st rows, the latch section 171b latches the outer code parity for each column. For example, the processing result “0th column (191)” using the data for the symbol B_{191,0} in the 0th column of the 191st row is the outer code parity B_{192,0}-B_{207,0} of the 0th column, and the processing result “1st column (191)” using the data for the symbol B_{191,1} in the 1st column of the 191st row is the outer code parity B_{192,1}-B_{207,1} of the 1st column. In each column, when processing is completed based on the data for the symbols in each column of the 0th row to the 191st row (YES in step S40), the processing proceeds to step S50. In step S50, the selector 174 performs switching control to sequentially transfer the outer code parities B_{192,0}-B_{207,0}, B_{192.1}-B_{207.1}, . . . to the buffer memory 300 (external circuit).

In step S60, the selector 173 performs switching control so that the data for each symbol in the outer code parity transferred to the buffer memory 300 is transferred to the PI calculation circuit 172. This enables the PI calculation circuit 172 to perform a calculation process for the inner code parities of the 192nd to 207th rows configuring outer code parities in addition to the inner code parities of the 0th to 191st row.

In step S70, the selector 174 checks whether the outer code parity B_{192,171}-B_{207,171} of the 171st row has been transferred to the buffer memory 300 based on the counter value of the counter 175. The calculation results “0th row (171)”, “1st row (171)”, . . . “207th row (171)” of the PI calculation circuit 172 based on the data for each symbol configuring the corrected code and outer code parity of the 171st row are the inner code parities of each row. When the transfer of the outer code parity of the 171st column is completed (YES in step S70), the process proceeds to step S80. In step S80, as shown by (a2) and (d2) in FIG. 7B, the selector 174 performs switching control so that the inner code parities held in the temporary memory 190 is sequentially transferred from the inner code parity of the 0th row.

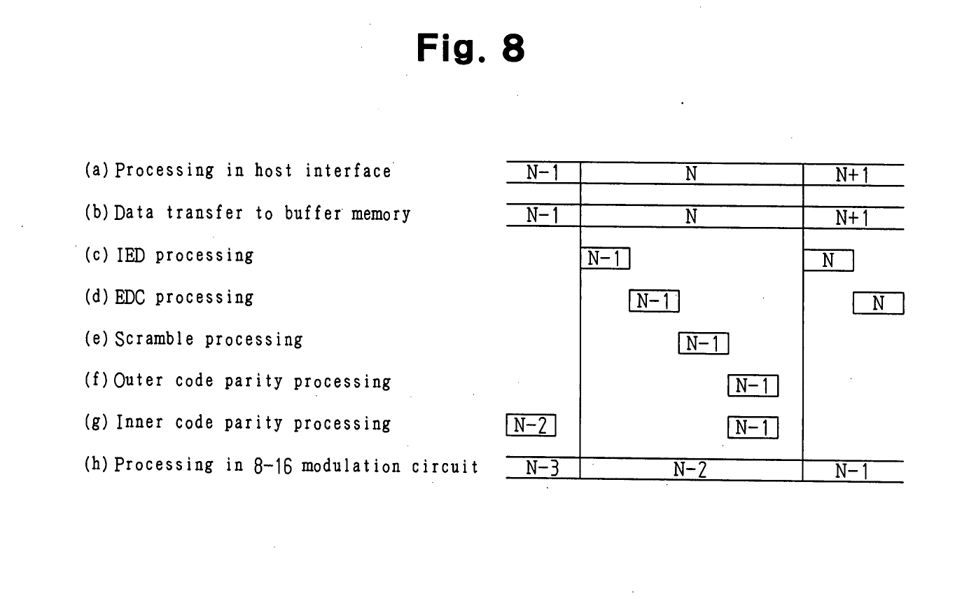

In FIG. 8, (a) and (b) show the blocks corresponding to the data transferred to the buffer memory 30 from the host interface. Further, (c) to (h) in FIG. 8 respectively show the block corresponding to the data to which an IED has been added, the data to which an EDC has been added, the data that has undergone the scramble process, the data to which an outer code parity has been added, the data to which an inner code parity has been added, and the data that has been processed by the 8-16 modulation circuit. In the preferred embodiment, the calculation of the outer code parity and the inner code parity is performed simultaneously, or in parallel. This shortens the time for calculating the error correction code. Further, the time during which the buffer memory 300 is occupied to calculate the outer and inner code parities is shortened. Thus, even when a high speed data recording process is performed, the time other circuits have to wait to access the buffer memory is shortened.

In the preferred embodiment, the cycle during which the PO calculation circuit 171 and the PI calculation circuit 172 each perform a single calculation is equal to or shorter than the cycle in which data is transferred with the buffer memory 300. For example, for one clock cycle of an operation clock signal for the digital signal processing device 100, the PO calculation circuit 171 and the PI calculation circuit 172 each perform a single calculation.

In a case where the buffer memory 300 is an SDRAM, the accessing of the buffer memory 300 requires three clock cycles, one clock cycle for the designation of a row address, one clock cycle for the designation of a column address, and one clock cycle for a precharging operation. However, the data for the symbols read to calculate the outer code parity may be stored in the buffer memory storage sections along the direction of rows. In this case, when the buffer memory 300 is accessed using a page mode in which columns addresses are designated while the row address is fixed, the access cycle of the buffer memory 300 is one clock cycle since the storage sections are designated just by designating the column addresses.

The preferred embodiment has the advantages described below.

(1) At the same time as when sequentially retrieving the data for the symbols in each column shown in FIG. 2 to calculate the outer code parity, the data for the symbols is retrieved to calculate the inner code parity. This increases the calculation speed for the error correction code.

(2) When transferring the outer code parity to the buffer memory 300, the data for each symbol configuring the outer code parity is retrieved in the PI calculation circuit 172 to calculate the inner code parity. Since the inner code parity is calculated, there is no need to read the outer code parity transferred to the buffer memory 300. This reduces the number of times the buffer memory 300 is accessed.

(3) When calculating the outer code parity for the 171st column, the temporary memory 190 temporarily holds the calculation result of the PI calculation circuit 172 that is based on the corrected code for the corresponding column and the symbol data for the outer code parity in the 171st column. This smoothly performs the processing related with the calculation of the outer code parity for the 171st column and the processing related with the transfer of the outer code parity.

(4) The inner code parities are transferred to the buffer memory 300 after all of the outer code parities are transferred to the buffer memory 300. This prevents the transfer of the inner code parity from interfering with the transfer of other processes in the ECC processing circuit 170.

(5) The temporary memory 190 has storage sections, each of which has a capacity for storing the data amount of the inner code parity corresponding to each row. When the temporary memory 190 stores a new calculation result, the corresponding storage section is overwritten. This calculates the inner code parity and the outer code parity in the required minimum storage section simultaneously or in parallel.

It should be apparent to those skilled in the art that the present invention may be embodied in many other specific forms without departing from the spirit or scope of the invention. Particularly, it should be understood that the present invention may be embodied in the following forms.

When calculating the inner code parity, a new calculation result obtained by reading the previous calculation result from the temporary memory 190 does not have to be held in the storage section in which the previous calculation result is stored. For example, by using a temporary memory having an enlarged storage section, the calculation results may be stored in different storage sections. In this case, the above advantage (1) is also obtained.

The inner code parity does not have to be transferred to the buffer memory 300 after all of the outer code parities are transferred to the buffer memory 300. In this case, the above advantage (1) is also obtained.

After temporarily storing the outer code parities in the buffer memory 300, the stored outer code parities may be read to calculate the inner code parities for the 192nd to 207th inner code parities. In this case, the above advantage (1) is also obtained.

In the process shown in FIG. 5, the data for the symbols configuring a first symbol group is sequentially retrieved to continuously calculate first error correction codes in the first step. Further, the data for the symbols retrieved to calculate the first error code is used to intermittently calculate second error correction codes. However, the first and second steps do not have to be performed as illustrated in FIG. 5. For example, the inner code parities may be calculated in the first step and the outer code parities may be calculated in the second step. In this case, the intermediate data, related to the outer code parities and generated when calculating the second error correction codes in the second step, is temporarily stored in the third step.

The generation of the first to third steps does not have to be performed by the exclusive circuits shown in FIG. 4 and may be performed by a program (software) executed by a computer. The program may be stored or recorded in a computer readable medium. When executing a program that performs the process of FIG. 5, steps S20 and S20 may be performed in any order.

The format of the code word including an error correction code is not limited to the DVD data format shown in FIG. 1. It is only required that the format be such that a corrected code having a predetermined data amount be arranged in rows and columns of symbols having a predetermined number of bits and that the first error correction codes and the second error correction codes be respectively added to the rows and columns. In other words, the present invention may be applicable to a data recording device for an optical disc other than a DVD.

The present examples and embodiments are to be considered as illustrative and not restrictive, and the invention is not to be limited to the details given herein, but may be modified within the scope and equivalence of the appended claims.

1. A method for generating an error correction code for data units represented by symbols, the symbols being arranged in an array of rows and columns, either one of each row of symbols and each column of symbols defining a first symbol group and the other one thereof defining a second symbol group, a first error correction code being added to each of the first symbol groups, a second error correction code being added to each of the second symbol groups, the method comprising:
sequentially reading data for each symbol of each first symbol group and continuously calculating the first error correction code corresponding to that first symbol group;
acquiring the data for each symbol used to calculate the first error correction code corresponding to each first symbol group and intermittently calculating the second correction codes corresponding to the second symbol groups, wherein intermediate data is generated when the second error correction codes are being calculated; and
temporarily holding the intermediate data,
wherein said acquiring data for each symbol used to calculate the first error correction code includes calculating the second error correction codes based on the data for the symbols read in said sequentially reading data for each symbol of each first symbol group and the temporarily held intermediate data, said temporarily holding the intermediate data including updating the temporarily held intermediate data whenever said acquiring data for each symbol used to calculate the first error correction code is performed.

2. The method according to claim 1, wherein said acquiring data for each symbol used to calculate the first error correction code includes obtaining initial data and acquiring the data for the symbols read when calculating the first error correction code corresponding to the first symbol group that is first processed to calculate the associated second error correction code, said acquiring data for each symbol used to calculate the first error correction code further including acquiring the data for the symbols read when calculating the first error correction codes corresponding to the first symbol groups processed after the one that is first processed and retrieving the intermediate data temporarily held in said temporarily holding the intermediate data to calculate the associated second error correction codes.

3. The method according to claim 1, wherein each of the first error correction codes is configured by a predetermined number of symbols, the second error correction codes including an error correction code added to a plurality of symbols configured by collecting one symbol from each first correction code of the first symbol groups, the method further comprising:
transferring the first correction code to an external circuit whenever calculating the first correction code;
calculating the second error correction code using the data for the symbols of the first correction code, the intermediate data being generated when the second error correction code is calculated; and
temporarily holding the intermediate data generated in said calculating the second error correction code,
wherein said calculating the second error correction code includes calculating the second error correction codes using the intermediate data temporarily held when said temporarily holding the intermediate data generated in said calculating the second error correction code was previously performed.

4. The method according to claim 3, further comprising;
when calculating a final one of the first error correction codes in said sequentially reading data for each symbol of each first symbol group, temporarily holding the second correction code configured by the calculation result of said retrieving data for each symbol used to calculate the first error correction code using the data for the symbols of the corresponding first symbol group and the calculation result of said temporarily holding the intermediate data generated in said calculating the second error correction code using data for the symbols of the finally calculated error correction code.

5. The method according to claim 4, further comprising:
transferring the second error correction code held in said temporarily holding the second correction code to the external circuit after the transfer of all of the first error correction codes is completed in said transferring the first correction code to an external circuit.

6. A device for generating an error correction code for data units represented by symbols, the symbols being arranged in an array of rows and columns, either one of each row of symbols and each columns of symbols defining a first symbol group and the other one thereof defining a second symbol group, a first error correction code being added to each of the first symbol groups, a second error correction code being added to each of the second symbol groups, the device comprising:
a first calculation circuit for sequentially reading data for each symbol of each first symbol group and continuously calculating the first error correction code corresponding to that first symbol group;
a second calculation circuit for acquiring the data for each symbol read by the first error correction and intermittently calculating the second correction codes corresponding to the second symbol groups, wherein the second calculation circuit generates intermediate data when the second error correction codes are being calculated; and
a temporary memory, connected to the second calculation circuit, for temporarily holding the intermediate data,
wherein the second calculation circuit retrieves the intermediate data from the temporary memory, performs a predetermined calculation with the intermediate data and the acquired data for each symbol, and updates the temporarily held intermediate data.

7. The device according to claim 6, wherein the second calculation circuit acquires initial data and the data for the symbols read when calculating the first error correction code corresponding to the first symbol group that is first processed to calculate the associated second error correction code, and wherein the second calculation circuit further acquires the data for the symbols read by the first calculation circuit when calculating the first error correction codes corresponding to the first symbol groups processed after the one that is first processed and retrieves the intermediate data temporarily held in the temporary memory to calculate the associated second error correction codes.

8. The device according to claim 6 for use with an external circuit, wherein each of the first error correction codes is configured by a predetermined number of symbols, the second error correction codes including an error correction code added to a plurality of symbols configured by collecting one symbol from each first correction code of the first symbol groups, the device further comprising:
an interface for transferring the first correction codes to the external circuit whenever the first calculation circuit calculates the first correction code,
wherein the second calculation circuit acquires data for the symbols of the first error correction codes and calculates the second error correction codes when the first error correction codes are transferred to the external circuit.

9. The device according to claim 8, wherein when the first calculation circuit calculates a final one of the first error correction codes, the temporary memory temporarily holds the calculation result that is generated by the second calculation circuit using the data for the symbols of the corresponding first symbol group and data for the symbols of the finally calculated error correction code.

10. The device according to claim 9, wherein the interface transfers the second error correction codes held in the temporary memory to the external circuit after all of the first error correction codes is transferred to the external circuit.
